(19) United States
(12) Patent Application Publication
(10) Pub. No.: US 2006/0175043 A1
(43) Pub. Date: Aug. 10, 2006

(54) Temperature conductor and method of making same

(76) Inventor: Hung-Tao Peng, Miao Lee Hsien (TW)

Correspondence Address: John & S. Egbert;Harrison & Egbert, 7th Floor, 412 Main Street, Houston, TX, 77002, US

(21) Appl. No.: 11/051,104

(22) Filed: Feb. 7, 2005

(51) Int. Cl. H05K 7/20

(52) U.S. Cl. 165/104.26; 165/104.33; 361/700

(57) ABSTRACT

The shaping method and structure of a temperature conductor includes a seat frame and a complex group of conductor pipes. Of which, the connecting side of conductor pipes is linked to the conduction seat frame. The close-type shared groove chamber is mounted into the conduction seat frame, such that connecting side of conductor pipes is linked to the shared groove chamber. The vacuum pumping can be performed for any optional conductor pipe, while other conductor pipes and shared groove chamber are pumped out simultaneously, thereby saving considerably the manufacturing time and process of temperature conductors in a cost-effective manner.

### RELATED U.S. APPLICATIONS

Not applicable.

### STATEMENT REGARDING FEDERALLY SPONSORED RESEARCH OR DEVELOPMENT

Not applicable.

### REFERENCE TO MICROFICHE APPENDIX

Not applicable.

### FIELD OF THE INVENTION

The present invention relates generally to a temperature conductor, and more particularly to an innovative temperature conductor that is designed with a shared groove chamber connected to various conductor pipes on the seat frame.

### BACKGROUND OF THE INVENTION

The temperature conductor, commonly known as a heat-radiating module of electronic element (such as a computer CPU), is generally composed of a seat frame and heat pipes or radiating fins. The objective of the present invention is to give an idea of how to combine the heat pipe with the seat frame. Typically, this device is designed with a structure of a single heat pipe and a seat frame, or a single seat frame combined with several heat pipes for more efficient heat radiation. However, this structure has the following problems in practical applications:

1. Vacuum pumping shall be required for the heat pipe to achieve a desirable heat-radiation effect. However, vacuum pumping is a time-consuming work (additional tests required) that is required for long-duration manufacturing of heat pipes, making it difficult to further reduce the cost.

2. Capillary tissues shall be added to inner side of heat pipe for a stronger heat transfer, e.g. inner mesh or metal particles additionally required. Owing to smaller internal aperture of heat pipe that makes it difficult for adding capillary tissues and leads to higher defective fraction, there is a possibility of more problems and higher cost for the structure of heat pipes, which call for innovative R&D after thoughtful deliberation in this industry.

To this end, the inventor has provided the present invention of practicability after deliberate design and evaluation based on his years of experience in the production, development and design of related products.

### BRIEF SUMMARY OF THE INVENTION

1. Based on this innovative and unique design that the shared groove chamber and various conductor pipes are connected via conduction seat frame, vacuum pumping can be performed against any conductor pipe to achieve the vacuum state of conductor pipes and shared groove chamber, thus saving considerably the manufacturing time and process of temperature conductors in a cost-effective manner.

2. Based on the unique design that capillary tissues are built-in the shared groove chamber of conduction seat frame, it's possible to transfer the capillary tissues from conductor pipe to shared groove chamber for an enhanced temperature transfer effect. And, thanks to a wider area of shared groove chamber than conductor pipe, capillary tissues function more easily and rapidly, thereby achieving a higher economical efficiency.

The above is a detailed description of the technical features of the present invention based on a typical preferred embodiment. Although the invention has been explained in relation to its preferred embodiment, it is to be understood that many other possible modifications and variations can be made without departing from the spirit and scope of the invention as hereinafter claimed.

### BRIEF DESCRIPTION OF THE SEVERAL VIEWS OF THE DRAWINGS

FIG. 1 shows a decomposed perspective view of the preferred embodiment of the present invention.

FIG. 2 shows a decomposed cutaway view of the preferred embodiment of the present invention.

FIG. 3 shows a combined cutaway view of the preferred embodiment of the present invention and the diagram of the flow of vacuum pumping.

### DETAILED DESCRIPTION OF THE INVENTION

The features and the advantages of the present invention will be more readily understood upon a thoughtful deliberation of the following detailed description of a preferred embodiment of the present invention with reference to the accompanying drawings.

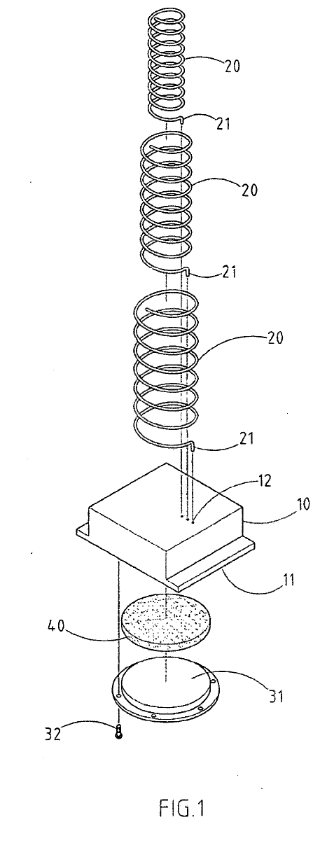

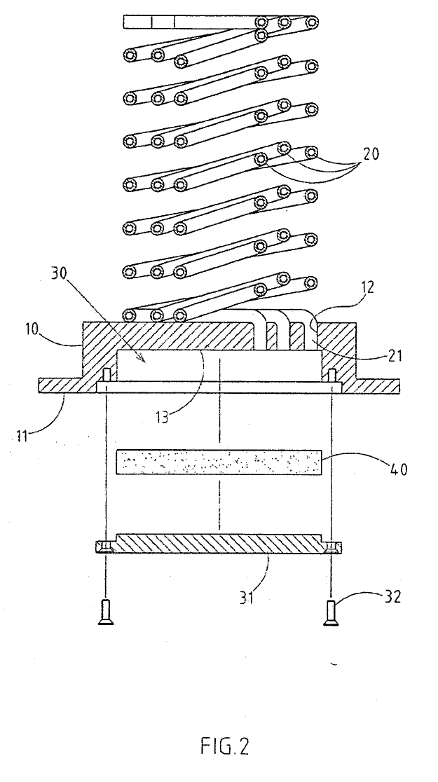

As shown in FIGS. 1-3, the shaping method and structure for a temperature conductor embodied in the present invention comprises:

a conduction seat frame 10, which is provided with a mounting surface 11 that can be mounted onto a preset heating unit, e.g. CPU or other electronic elements of computers;

a complex group of conductor pipes 20 with hollow piping. The connecting side 21 is linked to a preset side of the conduction seat frame 10 (top side in this embodiment);

a close-type shared groove chamber 30, which is placed within the conduction seat frame 10 that allows the connecting side 21 of conductor pipes 20 to be connected to the shared groove chamber 30.

Based on the aforementioned structure, the temperature conductor is manufactured as per the following procedures:

a. A close-type shared groove chamber 30 is placed within the conduction seat frame 10;

b. Some plug jacks 12 are mounted at the side wall of conduction seat frame 10, where connecting sides 21 of conductor pipes 20 are connected to the shared groove chamber 30;

c. The connecting sides 21 of conductor pipes 20 are air-tightly inserted into above-specified plug jacks 12;

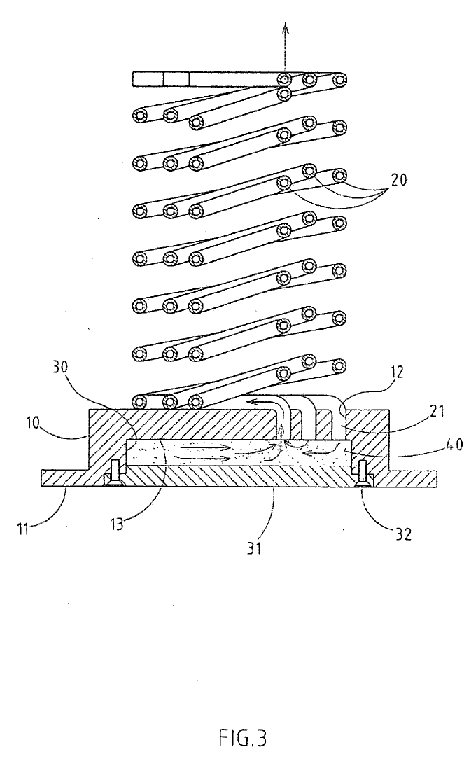

d. Vacuum pumping is performed for any optional conductor pipe 20 (as shown in FIG. 3). With the connection of the shared groove chamber 30, other conductor pipes 20 are pumped out simultaneously (the arrow in the figure indicates the direction of vacuum pumping);

e. Seal the aspiration hole of evacuated conductor pipe 20 (e.g. via welded sealing), providing a vacuum state of all conductor pipes 20 and shared groove chamber 30.

Of which, the gas sealing methods, such as gumming and welding, are applied to the pin joints of connecting side 21 of conductor pipes 20 and plug jacks 12.

A capillary tissue 40 is additionally installed within the shared groove chamber 30 of conduction seat frame 10. The so-called capillary tissue includes: fiber cotton, cloth, blanket, metal, porcelain and glass.

Of which, the shared groove chamber 30 of conduction seat frame 10 is designed with a groove 13 at mounting surface 11. And, a cover plate 31 is mounted at the open end of groove 13 for air-tightness. The cover plate 31 can be used for sealing by means of gumming, welding and screwing, as demonstrated by screw bolt 32 in this preferred embodiment.

1. A shaping method for a temperature conductor comprised of a conduction seat frame and a complex group of conductor pipes a connecting side of conductor pipes being linked to the conduction seat frame, said method comprising:
placing a close-type shared groove chamber within the conduction seat frame;
mounting a plurality of plug jacks at the side wall of conduction seat frame, where connecting sides of conductor pipes are connected to the shared groove chamber;
air-tightly inserting connecting sides of conductor pipes into said plug jacks;
performing vacuum pumping for any optional conductor, with the connection of the shared groove chamber, other conductor pipes being pumped out simultaneously; and
sealing an aspiration hole of evacuated conductor pipe, providing a vacuum state of all conductor pipes and shared groove chamber.

2. The shaping method as defined in claim 1, wherein gas sealing methods, such as gumming and welding, are applied to the pin joints of connecting side of said conductor pipes and plug jacks.

3. The shaping method as defined in claim 1, further comprising: installing a capillary tissue within the shared groove chamber of said conduction seat frame.

4. The shaping method as defined in claim 3, wherein said capillary tissue is comprised of fiber cotton, cloth, blanket, metal, porcelain and glass.

5. A temperature conductor comprising:
a conduction seat frame with a mounting surface being mounted onto a preset heating unit;
a complex group of conductor pipes, a connecting side of conductor pipes being linked to the conduction seat frame; and
a close-type shared groove chamber placed within the conduction seat frame the connecting side of conductor pipes being connectable to the shared groove chamber.

6. A temperature conductor as defined in claim 5, wherein a shared groove chamber of said conduction seat frame is is comprised of a groove at mounting surface, a cover plate being mounted at the open end of groove for air-tightness.

7. A temperature conductor as defined in claim 6, wherein said cover plate is sealable by gumming, welding and screwing.

8. A temperature conductor as defined in claim 5, further comprising: a capillary tissue mounted into the shared groove chamber of said conduction seat frame.

9. A temperature conductor as defined in claim 8, wherein said capillary tissues are comprised of fiber cotton, cloth, blanket, metal, porcelain and glass.
